(19) United States
(12) Patent Application Publication
(10) Pub. No.: US 2014/0204554 A1
(43) Pub. Date: Jul. 24, 2014

(54) ELECTRONIC DEVICE WITH ELECTROMAGNETIC INTERFERENCE PROTECTION

(71) Applicant: ASKEY COMPUTER CORP., NEW TAIPEI CITY (TW)

(72) Inventor: Su-Huan Yu, New Taipei City (TW)

(73) Assignee: ASKEY COMPUTER CORP., NEW TAIPEI CITY (TW)

(21) Appl. No.: 13/786,482

(22) Filed: Mar. 6, 2013

(30) Foreign Application Priority Data
Jan. 22, 2013 (TW) 102102394

(51) Int. Cl. H05K 1/14; H05K 1/02

(52) U.S. Cl. CPC H05K 1/14; H05K 1/0216
USPC 361/784

(57) ABSTRACT

An electronic device with electromagnetic interface protection including a first printed circuit board, a second printed circuit board, a shielding member, and a first fixing member is provided. The shielding member is located between the first printed circuit board and the second printed circuit board. A first end of the shielding member is fixed to the first printed circuit board, and the first fixing member is buckled to a second end of the shielding member so that the shielding member is fixed to the second printed circuit board.

### CROSS-REFERENCE TO RELATED APPLICATION

This application claims the priority benefit of Taiwan application serial no. 102102394, filed on Jan. 22, 2013. The entirety of the above-mentioned patent application is hereby incorporated by reference herein and made a part of this specification.

### BACKGROUND

1. Technical Field

The invention relates to an electronic device. Particularly, the invention relates to an electronic device with electromagnetic interference (EMI) protection.

2. Related Art

Electromagnetic waves can be emitted from a circuit of an electronic device and transmitted through the atmosphere, or transmitted through electric wires. Various electromagnetic waves generated by the circuit of the electronic device probably degrades performance of a peripheral electronic device, and produces noises on the peripheral electronic device to damage images formed by the peripheral electronic device, which may shorten a service life of the peripheral electronic device, and cause malfunction of the peripheral electronic device. Moreover, the electromagnetic waves may also be harmful to human body. Therefore, in order to effectively shield the electromagnetic waves, related practitioners actively develop components used for shielding or preventing the electromagnetic interference (EMI).

Regarding an existing technique, an EMI shielding member is generally configured between two printed circuit boards in the electronic device to resolve the above problem. In a conventional assembling process, two ends of the EMI shielding member are welded on the two printed circuit boards. However, if the printed circuit boards are required to be repaired, a de-soldering operation has to be first performed to detach the printed circuit boards, and thereafter the welding operation has to be again performed to weld the EMI shielding member to the printed circuit boards, which may cause convenience and waste in the assembling process.

### SUMMARY

The invention is directed to an electronic device with electromagnetic interference (EMI) protection, in which printed circuit boards are easy to be detached from a shielding member.

The invention provides an electronic device with electromagnetic interference protection including a first printed circuit board, a second printed circuit board, a shielding member, and a first fixing member. The shielding member is located between the first printed circuit board and the second printed circuit board. The shielding member has a first end and a second end opposite to each other. The first end of the shielding member is fixed to the first printed circuit board. The first fixing member is fixed to the second printed circuit board, and is buckled to the second end of the shielding member, so as to fix the shielding member to the second printed circuit board.

In an embodiment of the invention, the first fixing member has a first clamping portion and a first buckling portion. The shielding member has a first engaging portion. The first clamping portion clamps the second end of the shielding member, and the first engaging portion is buckled to the first buckling portion, so as to buckle the first fixing member to the second end of the shielding member.

In an embodiment of the invention, the shielding member has a bending portion. The bending portion is bended to form the first engaging portion.

In an embodiment of the invention, the first fixing member further has a first welding portion. The first clamping portion is connected to the first welding portion, and the first welding portion is welded to the second printed circuit board to fix the first fixing member to the second printed circuit board.

In an embodiment of the invention, the shielding member has a through opening, and when the first clamping portion clamps the second end of the shielding member, the first engaging portion penetrates through the through opening and is buckled to the first buckling portion.

In an embodiment of the invention, the electronic device with electromagnetic interference protection further includes a second fixing member. The second fixing member is buckled to the first end of the shielding member to fix the shielding member to the first printed circuit board.

In an embodiment of the invention, the second fixing member has a second welding portion, a second clamping portion and a second buckling portion. The second clamping portion is connected to the second welding portion, and the second welding portion is welded to the first printed circuit board to fix the second fixing member to the first printed circuit board. The shielding member further has a second engaging portion. The second clamping portion clamps the first end of the shielding member, and the second engaging portion is buckled to the second buckling portion, so as to buckle the second fixing member to the first end of the shielding member.

In an embodiment of the invention, the electronic device with electromagnetic interference protection further includes an auxiliary fixing member. The auxiliary fixing member is located between the first printed circuit board and the second printed circuit board, and directly faces to the shielding member. The auxiliary fixing member has a first end and a second end opposite to each other. The first end of the auxiliary fixing member is fixed to the first printed circuit board, and the second end of the auxiliary fixing member is fixed to the second printed circuit board.

In an embodiment of the invention, a material of the auxiliary fixing member includes metal or nonmetal.

In an embodiment of the invention, a material of the shielding member includes metal.

In an embodiment of the invention, the first end of the shielding member is welded to the first printed circuit board.

According to the above descriptions, in the electronic device with electromagnetic interference protection provided by the invention, by buckling the fixing member to the shielding member, the shielding member is fixed between the printed circuit boards to serve as a device for shielding or preventing the electromagnetic interference. When the printed circuit board is to be repaired, the buckling relation between the fixing member and the shielding member can be easily released by simply pressing the shielding member through an external force. In this way, the printed circuit board can be detached from the shielding member, which facilitates disassembling and reworking of the printed circuit board.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of an electronic device with electromagnetic interference (EMI) protection according to an embodiment of the invention.

FIG. 2 is a schematic diagram of the electronic device with EMI protection of FIG. 1 viewed from another viewing angle.

FIG. 3 is a schematic diagram of an electronic device with EMI protection according to another embodiment of the invention.

FIG. 4 is a schematic diagram of the electronic device with EMI protection of FIG. 3 viewed from another viewing angle.

FIG. 5 is a side view of an electronic device with EMI protection according to still another embodiment of the invention.

### DETAILED DESCRIPTION OF DISCLOSED EMBODIMENTS

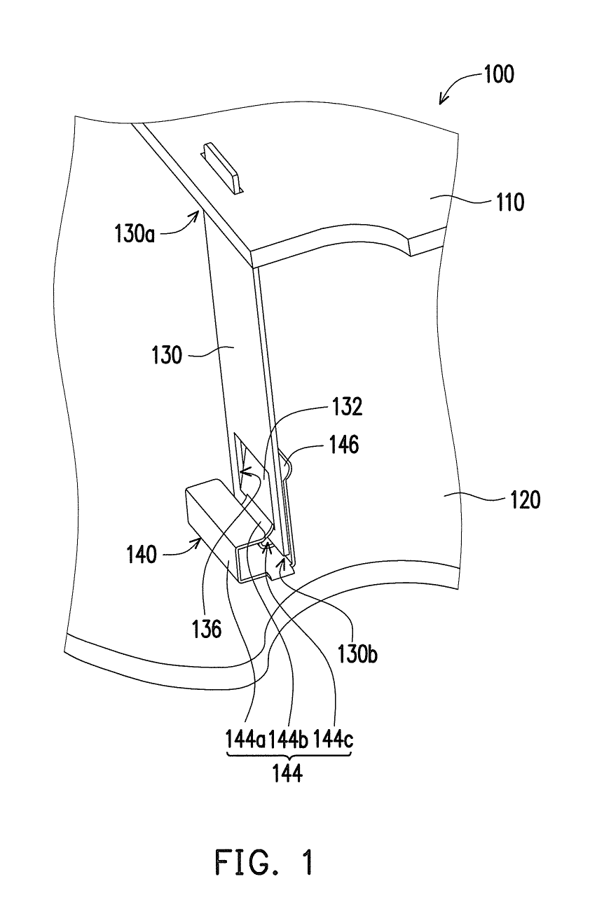

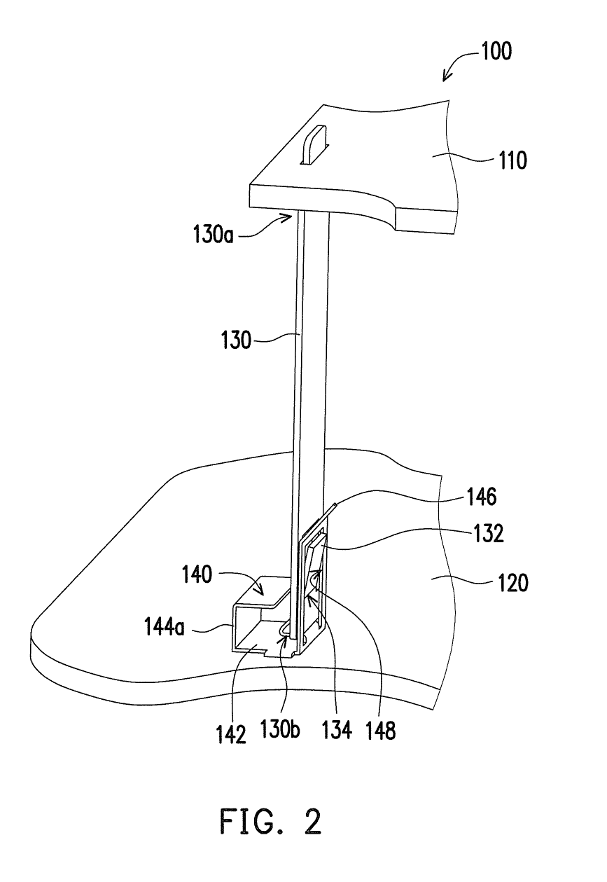

FIG. 1 is a schematic diagram of an electronic device with electromagnetic interference (EMI) protection according to an embodiment of the invention. FIG. 2 is a schematic diagram of the electronic device with EMI protection of FIG. 1 viewed from another viewing angle. It should be noticed that only a part of the components of the electronic device are illustrated in FIG. 1 and FIG. 2 to facilitate the description. Referring to FIG. 1 and FIG. 2, in the present embodiment, the electronic device with EMI protection 100 includes a first printed circuit board 110, a second printed circuit board 120, a shielding member 130, and a first fixing member 140, where a material of the shielding member 130 is, for example, metal, and the shielding member 130 is disposed between the first printed circuit bard 110 and the second printed circuit board 120 to serve a device for shielding or preventing the EMI. It should be noticed that the type of the electronic device is not limited by the invention, and as long as the electronic device has two or more printed circuit boards, it can be used as the electronic device with EMI protection of the present embodiment.

In the present embodiment, the first fixing member 140 is fixed to the second printed circuit board 120. The shielding member 130 has a first end 130a and a second end 130b opposite to each other. The first end 130a of the shielding member 130 is fixed to the first printed circuit board 110. The first fixing member 140 is buckled to the second end 130b of the shielding member 130, so as to fix the shielding member 130 to the second printed circuit board 120.

In this way, in the electronic device with EMI protection 100, by buckling the first fixing member 140 to the shielding member 130, the shielding member 130 is fixed to the second printed circuit board 120 to serve as a device for shielding or preventing the EMI, where the first end 130a of the shielding member 130 is, for example, welded to the first printed circuit board 110. Therefore, when the printed circuit board (the first printed circuit board 110 or the second printed circuit board 120) is to be repaired, the buckling relation between the first fixing member 140 and the shielding member 130 can be easily released by simply pressing the shielding member 130 through an external force without performing a de-soldering operation. In this way, the second printed circuit board 120 can be detached from the shielding member 130, i.e., the first printed circuit board 110 and the second printed circuit board 120 can be disassembled, so as to rework/repair the first printed circuit board 110 and/or the second printed circuit board 120.

In the present embodiment, the shielding member 130 has a first engaging portion 132, a bending portion 134 and an opening 136, where the bending portion 134 is bended outwards to form the first engaging portion 132 and form the opening 136.

Moreover, the first fixing member 140 has a first welding portion 142, a first clamping portion 144, a first buckling portion 146 and a through opening 148, where the first welding portion 142 is welded to the second printed circuit board 120 to fix the first fixing member 140 to the second printed circuit board 120, though the method of fixing the first fixing member to the second printed circuit board is not limited by the invention. In detail, one end of the first welding portion 142 is extended and bended to form the first buckling portion 146, and the through opening 148 is adjacent to the first buckling portion 146. The first clamping portion 144 is connected to the first welding portion 142. In detail, the first clamping portion 144 has a first bending section 144a, an abutting section 144b and a containing slot 144c, where one end of the first welding portion 142 is extended to form the bending section 144a, and the abutting section 144b is connected to the containing slot 144c.

When the bottom of the shielding member 130 (the second end 130b of the shielding member 130) is inserted into the containing slot 144c, the abutting section 144b of the first clamping portion 144 clamps the second end 130b of the shielding member 130, and the first engaging portion 132 penetrates through the through opening 148 and is bucked to the first buckling portion 146, so as to buckle the first fixing member 140 to the second end 130b of the shielding member 130. In this way, two sides of the shielding member 130 are respectively fixed by the abutting section 144b of the first clamping portion 144 and the first buckling portion 146, and cannot be easily detached from the first fixing member 140, so that the first fixing member 140 can fix the shielding member 130 to the second circuit board 120.

Conversely, when the printed circuit board (the first printed circuit board 110 or the second printed circuit board 120) is to be repaired, the buckling relation between the first buckling portion 146 and the first engaging portion 132 can be easily released by simply pressing the first engaging portion 132 through an external force, so as to fetch the shielding member 130 from the containing slot 144c. In this way, the second circuit board 120 can be detached from the shielding member 130. It should be noticed that in the aforementioned embodiment, the first fixing member 140 fixed to the second printed circuit board 120 is taken as an example for descriptions. Certainly, in other embodiments, the first fixing member can also be fixed to the first printed circuit board, which may also achieve the effects of buckling and easy disassembling, and the invention is not limited thereto.

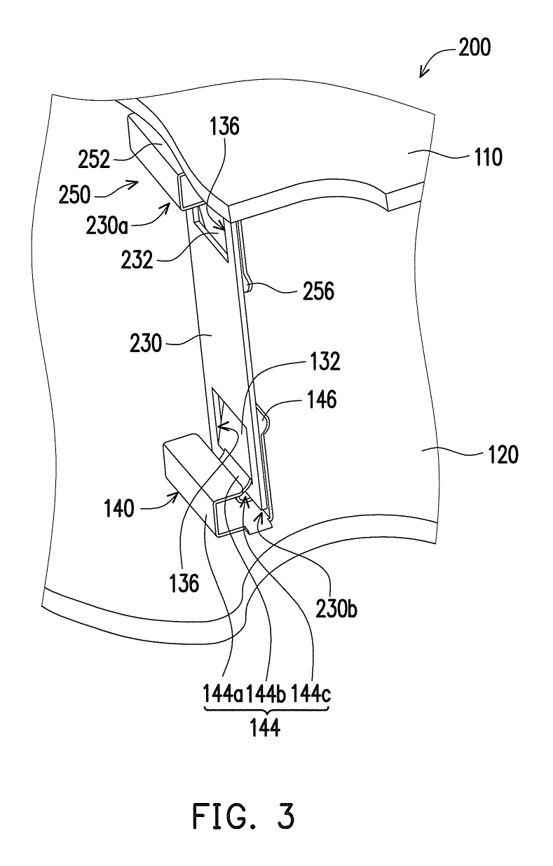

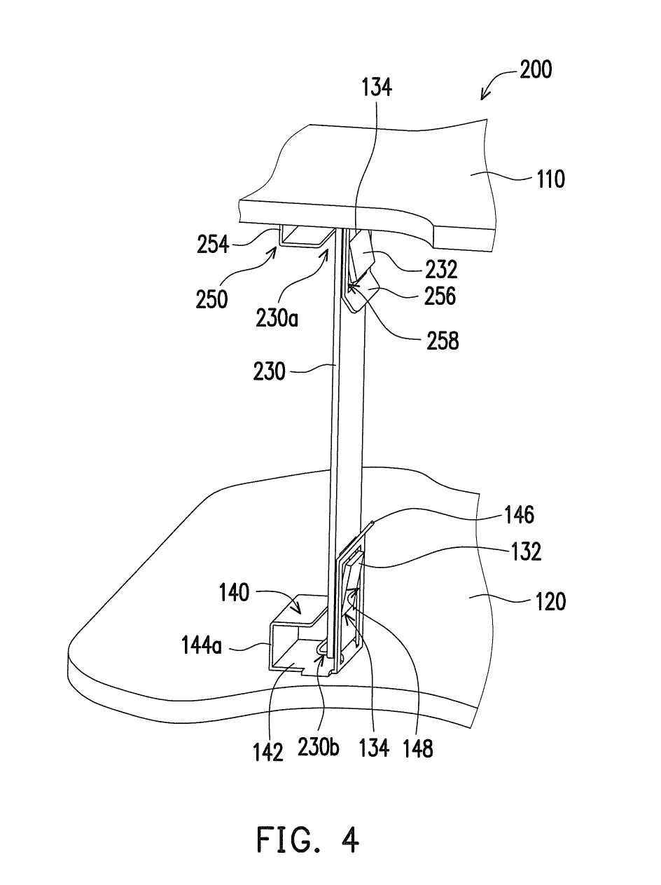

FIG. 3 is a schematic diagram of an electronic device with EMI protection according to another embodiment of the invention. FIG. 4 is a schematic diagram of the electronic device with EMI protection of FIG. 3 viewed from another viewing angle. It should be noticed that only a part of the components of the electronic device are illustrated in FIG. 3 and FIG. 4 to facilitate descriptions. Referring to FIG. 3 and FIG. 4, in the electronic device with EMI protection 200 of the present embodiment, a configuration method of the second printed circuit board 120, a shielding member 230 and the first fixing member 140 are similar to the configuration method of the second printed circuit board 120, the shielding member 130 and the first fixing member 140 of FIG. 1 and FIG. 2, and details thereof are not repeated.

A difference between the electronic device with EMI protection 200 of the present embodiment and the electronic device with EMI protection 100 of FIG. 1 and FIG. 2 is that a first end 230a of the shielding member 230 is not fixed to the first printed circuit board 110 through welding, i.e. the electronic device with EMI protection 200 further includes a second fixing member 250. The second fixing member 250 is buckled to the first end 230a of the shielding member 230 to fix the shielding member 230 to the first printed circuit board 110. In this way, the first end 230a of the shielding member 230 and the second end 230b of the shielding member 230 are respectively buckled to the fixing members (the first fixing member 140 and the second fixing member 250). In this way, when the printed circuit boards (the first printed circuit board 110 and the second printed circuit board 120) are to be repaired, the buckling relation between the shielding member 230 and one of the printed circuit boards (for example, the buckling relation between the second fixing member 250 and the shielding member 230) can be easily released by simply pressing the shielding member 230 through an external force, so as to detach the first circuit board 110 from the shielding member 230. Certainly, the buckling relation between the first fixing member 140 and the shielding member 230 can also be released to detach the first printed circuit board 110 and the second printed circuit board 120, so as to repair or rework the first printed circuit board 110 and the second printed circuit board 120.

In the present embodiment, a difference between the shielding member 230 and the shielding member 130 of FIG. 1 is that the shielding member 230 further has a second engaging portion 232 to serve as a component for buckling to the second fixed member 250. Besides, the function and shape of the shielding member 230 of the present embodiment are similar to the function and shape of the shielding member 130 of the aforementioned embodiment, so that configuration methods, functions and shapes of the second engaging portion 232, the bending portion 134 and the opening 136 of the shielding member 230 can refer to the configuration methods, functions and shapes of the first engaging portion 132, the bending portion 134 and the opening 136 of the shielding member 130 in FIG. 1 and FIG. 2, and details thereof are not repeated.

In the present embodiment, the second fixing member 250 has a second welding portion 252, a second clamping portion 254, a second buckling portion 256 and a through opening 258, where the second welding portion 252 is welded to the first printed circuit bard 110 to fix the second fixing member 250 to the first printed circuit board 110, though the method of fixing the second fixing member to the first printed circuit board is not limited by the invention. It should be noticed that due to the viewing angle of FIG. 3 and FIG. 4, a part of the components of the second clamping portion 254 is blocked by the first printed circuit board 110. In detail, one end of the second welding portion 252 is extended and bended to form the second buckling portion 256, and the through opening 258 is adjacent to the second buckling portion 256. The second clamping portion 254 is connected to the second welding portion 252.

Under above configuration, the second clamping portion 254 clamps the first end 230a of the shielding member 230, and the second engaging portion 238 is buckled to the second buckling portion 256 to buckle the second fixed member 250 to the first end 230a of the shielding member 230. In this way, two ends of the shielding member 230 are respectively buckled by the second fixing member 250 and the first fixing member 140, so that the shielding member 230 is fixed between the first printed circuit board 110 and the second printed circuit board 120 to serve as a device for shielding or preventing the EMI. When the printed circuit boards (the first printed circuit board 110 and the second printed circuit board 120) are to be repaired, the buckling relation between at least one of the first fixing member 140 and the second fixing member 250 and the corresponding printed circuit board (the second printed circuit board 120 or the first printed circuit board 110) can be easily released by simply pressing the first engaging portion 132 and/or the second engaging portion 238 through an external force without performing a de-soldering operation, so as to detach the first printed circuit board 110 and the second printed circuit board 120 to repair or rework the first printed circuit board 110 and the second printed circuit board 120.

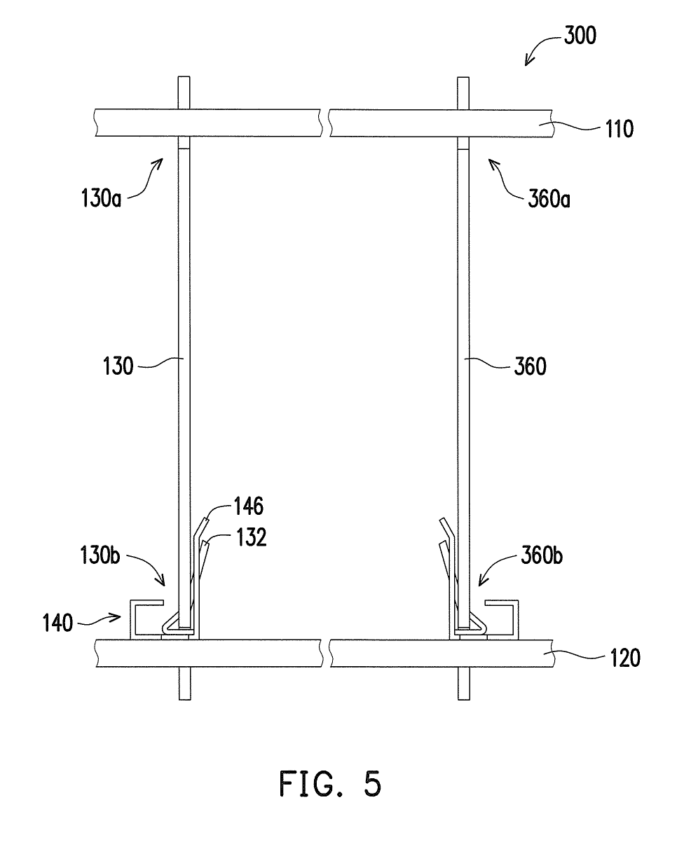

FIG. 5 is a side view of an electronic device with EMI protection according to still another embodiment of the invention. It should be noticed that only a part of the components of the electronic device are illustrated in FIG. 5 for descriptions. Referring to FIG. 5, in the electronic device with EMI protection 300 of the present embodiment, a configuration method of the first printed circuit board 110, the second printed circuit board 120, the shielding member 130 and the first fixing member 140 are similar to the configuration method of the first printed circuit board 110, the second printed circuit board 120, the shielding member 130 and the first fixing member 140 of FIG. 1 and FIG. 2, and details thereof are not repeated.

A difference between the electronic device with EMI protection 300 of the present embodiment and the electronic device with EMI protection 100 of FIG. 1 and FIG. 2 is that the electronic device with EMI protection 300 further includes an auxiliary fixing member 360, where the auxiliary fixing member 360 is located between the first printed circuit board 110 and the second printed circuit board 120.

In detail, the auxiliary fixing member 360 has a first end 360a and a second end 360b opposite to each other. The first end 360a of the auxiliary fixing member 360 is fixed to the first printed circuit board 110, and the second end 360b of the auxiliary fixing member 360 is fixed to the second printed circuit board 120. It should be noticed that the shielding member 130 in FIG. 5 is the same to the shielding member 130 in FIG. 1 and FIG. 2, i.e. the shielding member 130 only has one end fixed to the corresponding printed circuit board (the second printed circuit board 120) through buckling. Certainly, the shielding member 230 of FIG. 3 and FIG. 4 can also be used, which is not limited by the invention.

Under above configuration, the auxiliary fixing member 360 of the present embodiment directly faces to the shielding member 130, i.e. the shielding member 130 is fixed to one side between the first printed circuit board 110 and the second printed circuit board 120, and the auxiliary fixing member 360 is fixed to another side between the first printed circuit board 110 and the second printed circuit board 120 to enhance the fixing relation between the first printed circuit board 110 and the second printed circuit board 120.

Moreover, a material of the auxiliary fixing member 360 is metal or nonmetal. Therefore, when the auxiliary fixing member 360 is made of nonmetal, the auxiliary fixing member 360 can be used the fixing member used for fixing the first printed circuit board 110 and the second printed circuit board 120. On the other hand, when the auxiliary fixing member 360 is made of metal, besides that the auxiliary fixing member 360 can be used the fixing member used for fixing the first printed circuit board 110 and the second printed circuit board 120, the auxiliary fixing member 360 can also serve as a device for shielding or preventing the EMI.

In summary, in the electronic device with electromagnetic interference protection provided by the invention, by buckling the fixing member to the shielding member, the shielding member is fixed between the printed circuit boards to serve as a device for shielding or preventing the EMI, and the first end of the shielding member is, for example, welded to the first printed circuit board. In this way, when the printed circuit board is to be repaired, the buckling relation between the fixing member and the shielding member can be easily released by simply pressing the shielding member through an external force without performing a de-soldering operation. In this way, the printed circuit boards can be detached from the shielding member, i.e. the two printed circuit boards are disassembled, which facilitates disassembling and reworking of the printed circuit board.

Besides, the fixing members can be simultaneously disposed at the two ends of the shielding member, and the shielding member is assembled to the corresponding circuit boards through the fixing members. In this way, the fixing members can be used to facilitate disassembling and reworking the printed circuit boards.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An electronic device with electromagnetic interference protection, comprising:
a first printed circuit board;
a second printed circuit board;
a shielding member, located between the first printed circuit board and the second printed circuit board, and having a first end and a second end opposite to each other, wherein the first end of the shielding member is fixed to the first printed circuit board; and
a first fixing member, fixed to the second printed circuit board, and buckled to the second end of the shielding member, so as to fix the shielding member to the second printed circuit board.

2. The electronic device with electromagnetic interference protection as claimed in claim 1, wherein the first fixing member has a first clamping portion and a first buckling portion, the shielding member has a first engaging portion, the first clamping portion clamps the second end of the shielding member, and the first engaging portion is buckled to the first buckling portion, so as to buckle the first fixing member to the second end of the shielding member.

3. The electronic device with electromagnetic interference protection as claimed in claim 2, wherein the shielding member has a bending portion, and the bending portion is bended to form the first engaging portion.

4. The electronic device with electromagnetic interference protection as claimed in claim 2, wherein the first fixing member further has a first welding portion, the first clamping portion is connected to the first welding portion, and the first welding portion is welded to the second printed circuit board to fix the first fixing member to the second printed circuit board.

5. The electronic device with electromagnetic interference protection as claimed in claim 2, wherein the shielding member has a through opening, and when the first clamping portion clamps the second end of the shielding member, the first engaging portion penetrates through the through opening and is buckled to the first buckling portion.

6. The electronic device with electromagnetic interference protection as claimed in claim 1, further comprising:
a second fixing member, buckled to the first end of the shielding member to fix the shielding member to the first printed circuit board.

7. The electronic device with electromagnetic interference protection as claimed in claim 6, wherein the second fixing member has a second welding portion, a second clamping portion and a second buckling portion, the second clamping portion is connected to the second welding portion, and the second welding portion is welded to the first printed circuit board to fix the second fixing member to the first printed circuit board, the shielding member further has a second engaging portion, the second clamping portion clamps the first end of the shielding member, and the second engaging portion is buckled to the second buckling portion, so as to buckle the second fixing member to the first end of the shielding member.

8. The electronic device with electromagnetic interference protection as claimed in claim 1, further comprising:
an auxiliary fixing member, located between the first printed circuit board and the second printed circuit board, directly facing to the shielding member, and having a first end and a second end opposite to each other, wherein the first end of the auxiliary fixing member is fixed to the first printed circuit board, and the second end of the auxiliary fixing member is fixed to the second printed circuit board.

9. The electronic device with electromagnetic interference protection as claimed in claim 8, wherein a material of the auxiliary fixing member comprises metal or nonmetal.

10. The electronic device with electromagnetic interference protection as claimed in claim 1, wherein a material of the shielding member comprises metal.

11. The electronic device with electromagnetic interference protection as claimed in claim 1, wherein the first end of the shielding member is welded to the first printed circuit board.
